(19) United States
(12) Patent Application Publication
(10) Pub. No.: US 2019/0103250 A1
(43) Pub. Date: Apr. 4, 2019

(54) Charged Particle Beam Device

(71) Applicant: Hitachi High-Technologies Corporation, Tokyo (JP)

(72) Inventors: Toshiyuki YOKOSUKA, Tokyo (JP); Chahn LEE, Tokyo (JP); Hideyuki KAZUMI, Tokyo (JP); Hajime KAWANO, Tokyo (JP)

(21) Appl. No.: 16/136,534

(22) Filed: Sep. 20, 2018

(30) Foreign Application Priority Data
Sep. 29, 2017 (JP) 2017-189400

(51) Int. Cl. H01J 37/28; H01J 37/26

(52) U.S. Cl. CPC H01J 37/28; H01J 2237/1536; H01J 37/265

(57) ABSTRACT

There is proposed a charged particle beam device that generates a first signal waveform on the basis of scanning, the number of scanning lines of which is one or more, the scanning intersecting an edge of a pattern on a sample, generates a second signal waveform for a first area that is wider than the one scanning line on the basis of scanning, the number of scanning lines of which is larger than that of scanning for generating the first signal waveform, then determines a deviation between the generated first and second signal waveforms, and thereby determines, from the deviation, correction data used at the time of dimensional measurement.

### CLAIM OF PRIORITY

The present application claims priority from Japanese patent application JP 2017-189400 filed on Sep. 29, 2017, the content of which is hereby incorporated by reference into this application.

### BACKGROUND OF THE INVENTION

### 1. Field of the Invention

The present disclosure relates to a charged particle beam device, and in particular, a charged particle beam device that executes correction of pattern dimensions on the basis of a plurality of signals, or a plurality of pieces of image information, obtained by different scanning conditions.

### 2. Description of the Related Art

With miniaturization and three-dimensional structuralization of semiconductor patterns, a slight difference in shape exerts an influence on operating characteristics of a device, and accordingly there is an increasing need for shape management. Therefore, scanning electron microscopes (SEM: Scanning Electron Microscope) used for inspection and measurement of semiconductors further require high sensitivity and high accuracy compared with the prior art. Meanwhile, the miniaturization of shape causes a distance between patterns to be shortened, and consequently an influence on secondary electrons exerted when a sample has been electrified becomes obvious. In addition, as pattern dimensions get smaller, an influence of an error at the time of measuring pattern dimensions caused by electrification is increasing.

Japanese Patent No. 4901196 (corresponding U.S. Pat. No. 7,187,345) discloses a scanning method in which widening an interval between scanning lines suppresses accumulation of electrification caused by adjacent beam scanning performed before the electrification by beam scanning is moderated. Japanese Patent Application Laid-Open No. 2008-186682 discloses a scanning method in which scan coordinates of a scanning signal supplied to a scanning deflector are corrected by using a lookup table (LUT) for two-dimensional correction, thereby suppressing an influence of electrification.

### SUMMARY OF THE INVENTION

As disclosed in Japanese Patent No. 4901196, an influence of local electrification is moderated by widening an interval between scanning lines, which enables to form an image having no deviation in brightness in a field of view.

However, according to the scanning method disclosed in Japanese Patent No. 4901196, although a deviation in local electrification included in a field of view can be suppressed and an image in which a pattern shape is properly reflected can be generated, there is a case where the influence of the electrification varies in the field of view. More specifically, in the case of a center of a beam scanning area (field of view), the same electric charges also adhere to a periphery, and therefore the electrification does not deviate. However, the end of the field of view is put between a part to which electric charges adhere and a part having no electric charge (outside the field of view), and therefore an electric field that deflects an electron in a surface direction of a sample is generated, and consequently a difference in measurement accuracy occurs between the central part and end part of the field of view.

It is also considered that the LUT as disclosed in Japanese Patent Application Laid-Open No. 2008-186682 is used to correct the variation caused by the electrification. However, proper correction conditions change in various ways according to material properties of a sample, and observation conditions (scanning method, observation magnification, irradiation voltage, irradiation current, etc.), and therefore it is difficult to prepare such data beforehand.

Hereinbelow, a charged particle beam device will be described. An object of the charged particle beam device is to cope with both generation of an image in which a pattern shape is properly reflected, and measurement in which a decrease in accuracy caused by a positional difference in a field of view is suppressed.

As one aspect of achieving the above-described object, there is proposed a charged particle beam device including: a scanning deflector that scans a charged particle beam emitted from a charged particle source; a detector that detects a charged particle obtained on the basis of scanning of the charged particle beam applied to a sample; a computing device that generates a signal waveform on the basis of an output of the detector, and computes pattern dimensions of a pattern formed on the sample by using the signal waveform; and

a control device that controls the scanning deflector, wherein when the control device controls the scanning deflector to perform scanning, the number of scanning lines of which being one or more, for a first region intersecting an edge of the pattern on the sample, the computing device generates a first signal waveform on the basis of the charged particle detected by the detector, and when the control device controls the scanning deflector to perform scanning, the number of scanning lines of which being larger than that at the time of scanning the first region, for a first area that includes the first region, and that is wider than the first region, the computing device generates a second signal waveform on the basis of the charged particle detected by the detector, and the control device determines a deviation between the generated first and second signal waveforms.

### BRIEF DESCRIPTION OF THE DRAWINGS

FIG. 1 is a diagram illustrating an outline of a scanning electron microscope;

FIG. 2 is a drawing illustrating a sample surface electrification distribution in a field of view at the time of scanning by different scanning methods;

FIG. 3 is a graph illustrating a state in which a change in a beam irradiation position causes an arrival position to change;

FIG. 4 is a flowchart illustrating a step of comparing a signal waveform obtained by one-dimensional scanning with a signal waveform obtained by two-dimensional scanning to generate a correction map for correcting a beam arrival position on a two-dimensional image;

FIGS. 5A and 5B are drawings illustrating a first signal waveform and a second signal waveform in an embodiment;

FIG. 6 shows graphs each illustrating a relationship between a position (coordinates) in the field of view and a variation amount of an edge;

FIG. 7 is a drawing illustrating a correction map that indicates a correction amount at each position in the field of view;

FIG. 8 is a diagram illustrating, as an example, a semiconductor measurement system that includes a scanning electron microscope;

FIG. 9 is a drawing illustrating, as an example, a Graphical User Interface (GUI) screen used to set operating conditions of an SEM;

FIG. 10 is a drawing illustrating a first-signal-waveform obtainable area that is set in the field of view;

FIG. 11 is a drawing illustrating a positional relationship between edge position information obtained by one-dimensional scanning and an edge obtained by two-dimensional scanning;

FIG. 12 is a drawing illustrating an example in which matching is used to align an edge position obtained by one-dimensional scanning with an edge obtained by two-dimensional scanning; and

FIG. 13 is a drawing illustrating an example in which a measurement area for measuring a diameter of a hole pattern is set.

### DESCRIPTION OF THE PREFERRED EMBODIMENTS

In an embodiment described below, a charged particle beam device that is provided with a computing device for executing measurement of a pattern with high accuracy will be described. In addition, the charged particle beam device described below is controlled by a control device that is provided with: a computer processor; and a non-temporary computer readable medium. When the non-temporary computer readable medium is executed by the computer processor, the non-temporary computer readable medium is encoded by a computer instruction that causes a system controller to execute predetermined processing, and the charged particle beam device is controlled, and image processing is executed, according to a processing step as described below.

A pattern edge or the like is locally electrified by electron ray scanning, and consequently image deformation and abnormal contrast occur. In order to eliminate this phenomenon, changing a scanning method, for example, widening a scanning interval, is effective. However, an electrification distribution formed in a field of view (Field Of View: FOV) changes depending on the scanning method, and an ununiform magnification variation occurs in FOV. As the result of the ununiform magnification variation, a length measurement value varies depending on a scanning method and a position of an object to be observed in FOV, and therefore there is a case where it becomes difficult to cope with both the improvement in image visibility and the stable length measurement.

A charged particle beam device that corrects dimension values between a plurality of scanning methods, thereby enabling to cope with both of the visibility and the stable length measurement, and a pattern measuring device, will be described below.

The embodiment below describes, for example, a charged particle beam device provided with: a charged particle beam deflector that scans a charged particle beam emitted from a charged particle source; a detector that detects a charged particle obtained on the basis of scanning of the charged particle beam applied to a sample; and a computing device that generates a signal waveform on the basis of an output of the detector, and computes pattern dimensions of a pattern formed on the sample by using the signal waveform, wherein a first signal waveform is obtained beforehand by scanning from one line to several lines in X, Y directions of a sample surface on an object to be observed, a second signal waveform is obtained by an arbitrary scanning method, the first signal waveform is then compared with the second signal waveform to extract a deviation between two waveforms at each position in the field of view, and a waveform or an image is corrected according to the amount of deviation between the waveforms.

There is further described a pattern measuring device that is provided with a computing device that generates a signal waveform on the basis of a detection signal obtained by the charged particle beam device, and computes pattern dimensions of a pattern formed on the sample by using the signal waveform, in which a first signal waveform is compared with a second signal waveform to extract a deviation between two waveforms at each position in the field of view, and a waveform or an image is corrected according to the amount of deviation between the waveforms.

According to the above-described configuration, it is possible to cope with both the improvement in visibility and the stable length measurement by changing a scanning method, and pattern measurement, pattern recognition or the like can be performed with high accuracy.

As a device for measuring and inspecting a minute pattern of a semiconductor device with high accuracy, needs for a scanning electron microscope (Scanning Electron Microscope) are increasing. The scanning electron microscope is a device for detecting an electron or the like emitted from a sample. The scanning electron microscope generates a signal waveform by detecting such an electron, and measures, for example, a dimension between peaks (pattern edges).

Among electrons emitted from a sample, a secondary electron, the energy of which is low, is easily influenced by the electrification of the sample. An influence of electrification becomes obvious because of the miniaturization of patterns, and the use of a low dielectric constant material such as low-k, in recent years. For example, in a case where there exists a dielectric around a pattern to be measured, electrification may occur by scanning an electron beam, and a signal waveform shape may change. In other words, there is a case where high-accuracy measurement becomes difficult due to the deformation of the signal waveform caused by the electrification.

In addition, the electrification of the sample causes a path of a low-energy electron beam to be deflected, and therefore there is a case where it becomes difficult to cause a beam to arrive at a desired position. Therefore, in the minute pattern measurement in recent years, an influence of local electrification in proximity to an irradiation point becomes obvious, and therefore a scanning method in which local electrification is suppressed is coming to be used for a sample, the electrification of which is remarkable. As a method, there is, for example, a method in which one line is repeatedly scanned to form an image, and scanning in which an interval between scanning lines is widened. Even in the case of a pattern that is coming to have difficulty in observation at an end device, there is a case where the above-described scanning increases the signal amount at an observation point, and the visibility is improved.

Meanwhile, there arises a problem that when the above-described scanning method is used, the electrification distribution formed in the field of view changes, which causes the amount of deflection of primary electrons on the sample to change, and consequently dimensions vary. The embodiment below describes a charged particle beam device, or a pattern measuring device, wherein a dimension value obtained at the time of two-dimensional scanning is corrected on the basis of a signal waveform obtained by scanning from one line to several lines, the signal waveform having been little influenced by electrification.

More specifically, the embodiment below describes, for example, a pattern measuring device that is provided with: a charged particle source; a deflector that scans a charged particle beam emitted from the charged particle source on a sample; a detector that detects a secondary electron emitted by scanning the charged particle beam on the sample; an image memory that stores a signal obtained by scanning the charged particle beam on the sample; and a computing device that, on the basis of irradiation with the charged particle beam, measures pattern dimensions of a pattern formed on the sample, wherein a first signal waveform is obtained beforehand by scanning from one line to several lines in X, Y directions of a sample surface on an object to be observed, a second signal waveform is obtained by an arbitrary scanning method, the first signal waveform is then compared with the second signal waveform to extract a deviation between two waveforms at each position in the field of view, and a waveform or an image is corrected according to the amount of deviation between the waveforms. By using such a configuration, even in a case where an arbitrary scanning method is used, correcting dimensions on the basis of information related to the first signal waveform enables to cope with both an improvement in visibility by suppressing local electrification, and stable dimension length measurement.

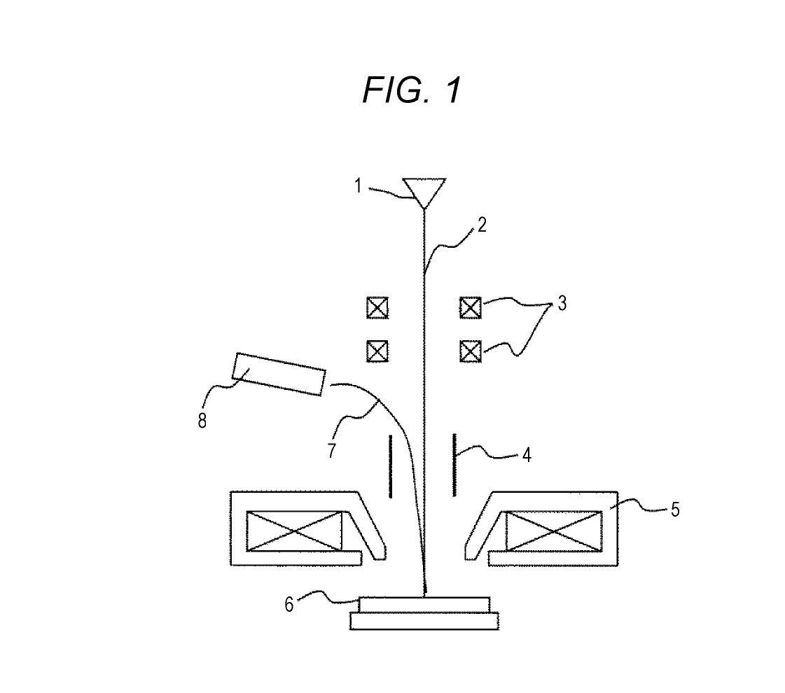

The embodiment below mainly describes a method for extracting a dimensional change caused by a difference in electrification in a field of view formed when two-dimensional scanning is performed, and a method for correcting the dimensional change. FIG. 1 is a schematic diagram illustrating a scanning electron microscope that is a kind of charged particle beam device.

An electron ray 2 (electron beam) generated by an electron gun 1 is converged by a condenser lens 3, and is finally converged on a sample 6 by an objective lens 5. A deflector 4 (scanning deflector) causes the electron ray 2 to be scanned on an electron ray scanning area of a sample. A primary electron is two-dimensionally scanned, a secondary electron and a backscattered electron 7, which are excited by irradiating the sample and are emitted from the sample, are detected by a detector 8, and an electron signal is converted into an image, thereby observing and measuring the sample.

The image obtained by two-dimensionally scanning the sample is displayed on a display device (not illustrated). Moreover, a dimension value corrected by the undermentioned correction method is also displayed on this display device.

In addition, the scanning electron microscope shown in FIG. 1 is provided with a control device (not illustrated). The control device controls each optical element of the electron microscope. Further, a negative voltage applying power source (not illustrated) is connected to a sample stage on which the sample 6 is placed. By controlling the negative voltage applying power source, the control device controls arrival energy with which the electron beam arrives at the sample. Moreover, the control is not limited to the above. The arrival energy with which the electron beam arrives at the sample may be controlled by controlling an acceleration power source that is connected between an accelerating electrode for accelerating the electron beam and an electron source. Furthermore, the SEM presented in FIG. 1 is provided with an image memory for storing a detection signal on a pixel basis. The detection signal is stored in the image memory.

Moreover, the scanning electron microscope presented in FIG. 1 is provided with a computing device (not illustrated). The computing device executes dimensional measurement of a pattern on the basis of image data stored in the image memory. More specifically, a profile waveform is formed on the basis of brightness information stored on a pixel basis, and dimensional measurement of a pattern is executed on the basis of interval information related to an interval between one peak and another peak of the profile waveform, or an interval between one peak and a starting point of the peak.

In a case where the sample is a dielectric, a two-dimensional electrification distribution is formed in a scanning area (field of view: FOV) during SEM observation. The electron that is mainly detected by the SEM is a secondary electron, the emission amount of which is large, and the energy of which is small (up to several eVs), and therefore is easily influenced by a slight amount of electrification formed on a surface. Therefore, in the SEM observation of an electrified sample, an obtained image changes depending on how electrification distribution is formed at the time of irradiation. In addition, the primary electron with which the sample is irradiated is also deflected by the electrification in the field of view, and consequently an arrival position changes. Parameters that determine the electrification distribution on the surface include: the energy of the primary electron, which influences the emission amount of the secondary electron; the amount of electric current; and the scanning sequence and scanning speed of the electron ray. In addition, even in the case of the same conditions on the device side, the electrification changes depending on material properties and a difference in shape.

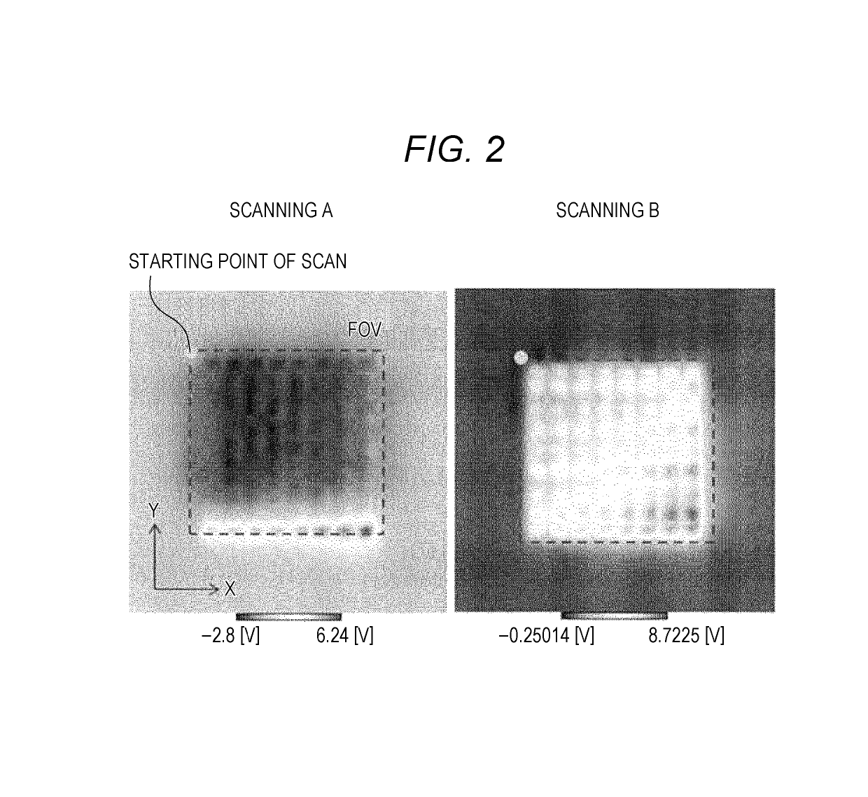

FIG. 2 shows electrification distribution on a sample obtained when scanning is performed by using two different scanning methods. Scanning A indicates electric potential distribution obtained when scanning is performed by TV scanning, and scanning B indicates electric potential distribution obtained by scanning with the interval between scanning lines in the Y direction of TV scanning widened. The upper left of the field of view is a starting point of scanning, and the lower right of the field of view is an endpoint of the scanning. In the scanning A, an immediately preceding scanned area is positively electrified, and areas that have been scanned until then are weakly and negatively electrified.

Meanwhile, in the scanning B, by widening an interval between scanning lines, positive electrification is distributed over a wide range in the field of view. Therefore, it is revealed that the electrification distribution differs depending on a difference in scanning method. For example, the scanning B employs a scanning method in which after the first scanning line and the second scanning line are first scanned with the interval equivalent to a plurality of scanning lines provided therebetween, the next scanning line is scanned at the center between the scanning lines that have been scanned, and the processing described above is repeated. According to such a scanning method, a deviation in electrification can be suppressed, the deviation in electrification being caused by scanning of a beam at a position in proximity to electrification in a state in which the electrification by beam scanning is not sufficiently moderated.

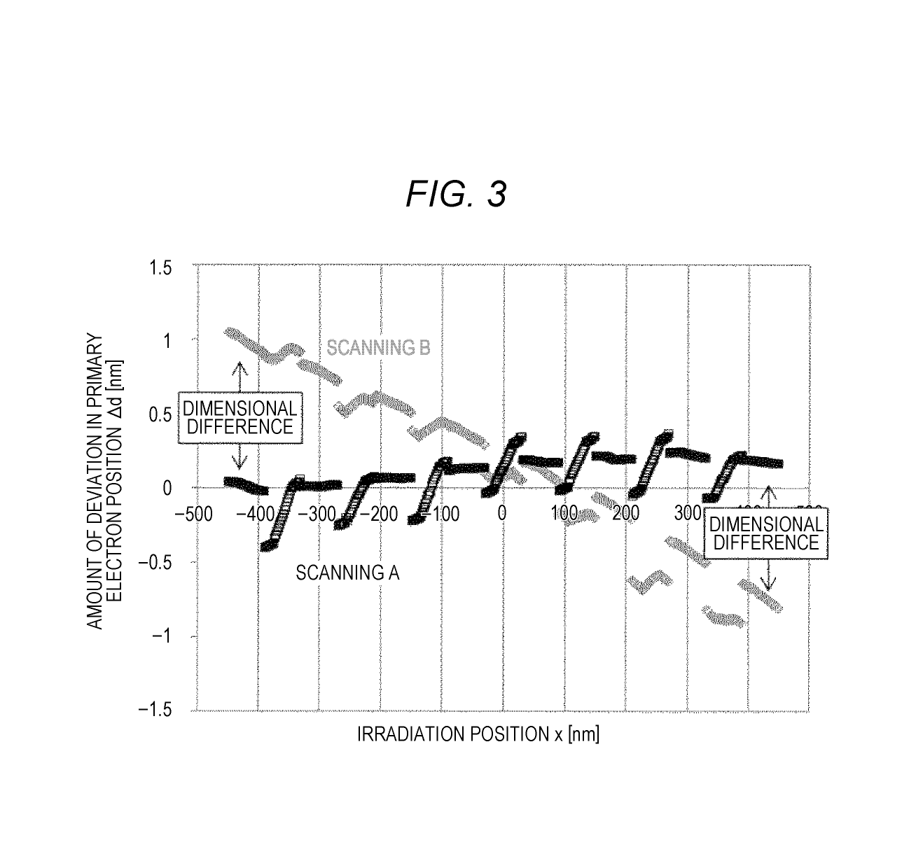

The result of evaluating an arrival position of a primary electron by using each scanning method at this point time is shown in FIG. 3. FIG. 3 shows an irradiation position in the field of view, and the amount of deviation in arrival positions of primary electrons. FIG. 3 reveals that in the case of the scanning A, if no electrification or the like occurs, an arrival position at which an electron beam primarily arrives substantially agrees with an actual arrival position over the whole area in the field of view, whereas in the case of the scanning B, the amount of deviation between the primary arrival position and the actual arrival position increases on the further outer side in the field of view. This is because in the case of the scanning B, electrification is formed as a surface in the field of view, which causes electric field distribution to change up to a higher position immediately above the field of view, and consequently the amount of deflection of primary electrons becomes large.

In addition, as revealed from the amount of deviation in arrival of primary electrons in the scanning B, the amount of deviation is not constant in the field of view, and increases on the further outer side in the field of view, and the amount of variation in dimensions differs depending on where a measurement pattern is located in the field of view. Therefore, correction of dimensions corresponding to coordinates in the field of view is required.

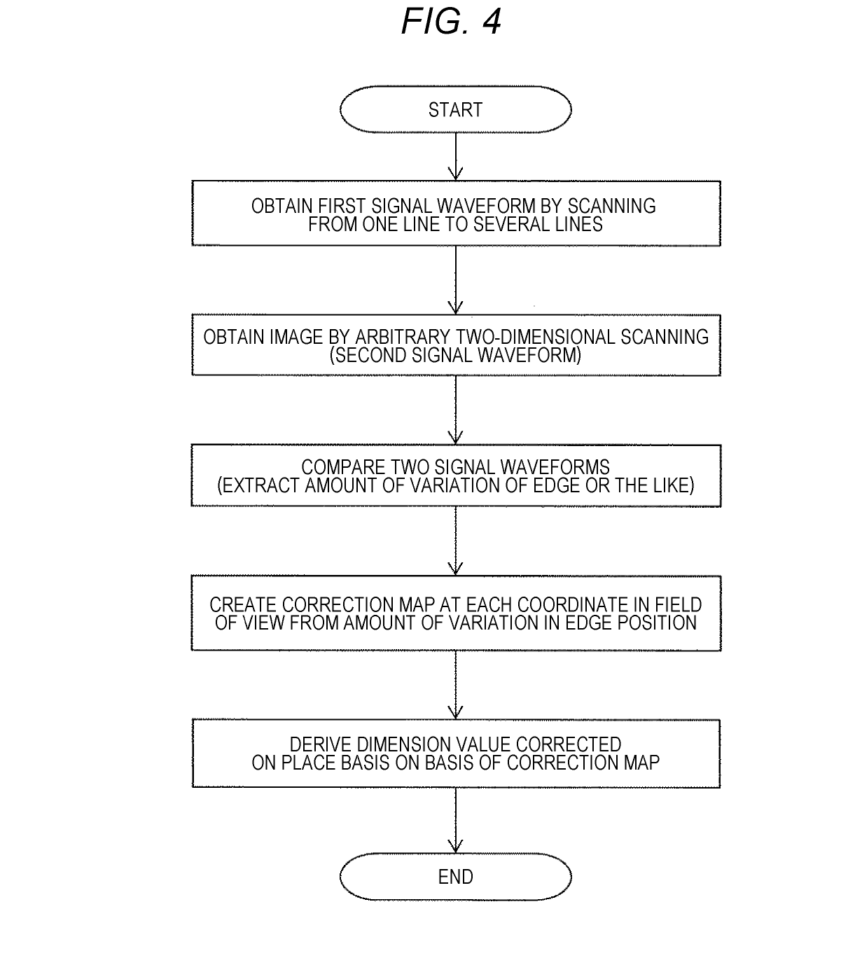

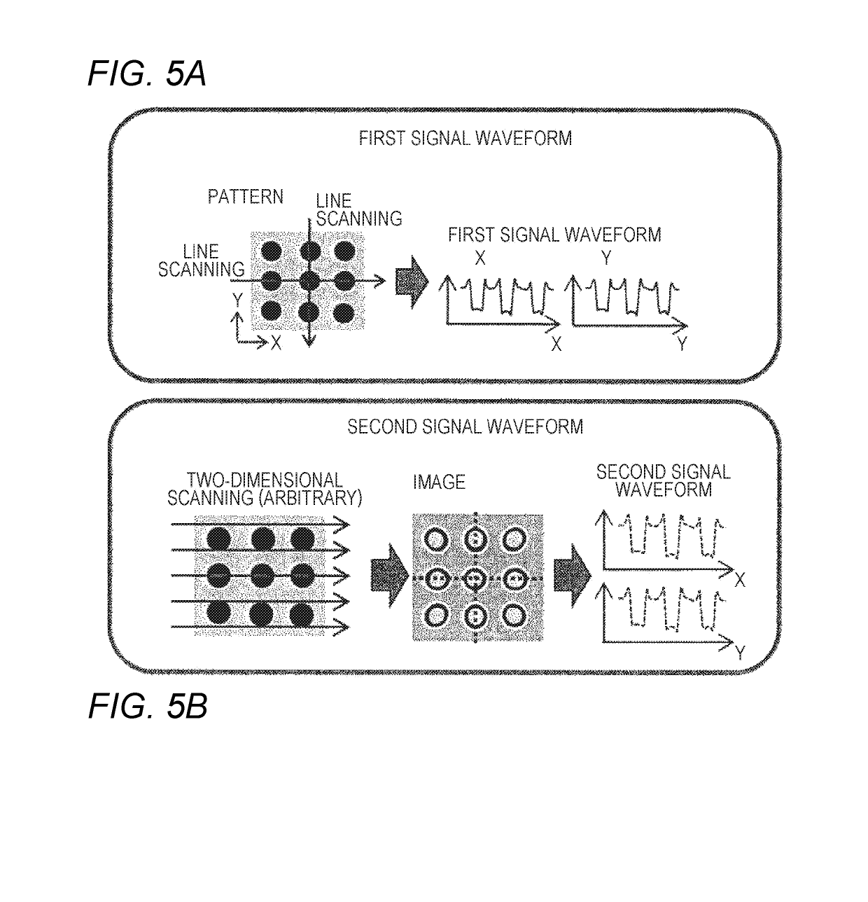

FIG. 4 shows a flow of correction of dimensions in the present example. As shown in FIGS. 5A and 5B, scanning from one line to several lines in X, Y directions is performed for an object to be measured, and the first signal waveform is obtained.

When S/N of the signal waveform is low, the number of lines may be increased. In addition, when irradiating an object with a charged particle such as a resist causes the object to have damage such as shrink, the number of irradiation lines may be reduced. As revealed from the electrification distribution in the scanning A, and from the amount of deviation in arrival of primary electrons, shown in FIGS. 2 and 3, even if the electrification is formed in a narrow range, an influence on primary electrons is small, and therefore the first signal waveform is used as a reference waveform.

Incidentally, as described below, the first signal waveform becomes a reference used to correct the second signal waveform. Therefore, the first signal waveform is obtained from an area in which an edge (a peak of a profile waveform) of a pattern is included at least in a scanning area, and relative positional relationship with the second signal waveform can be determined. Therefore, a beam is scanned along a region (first region) intersecting the edge of the pattern on the sample.

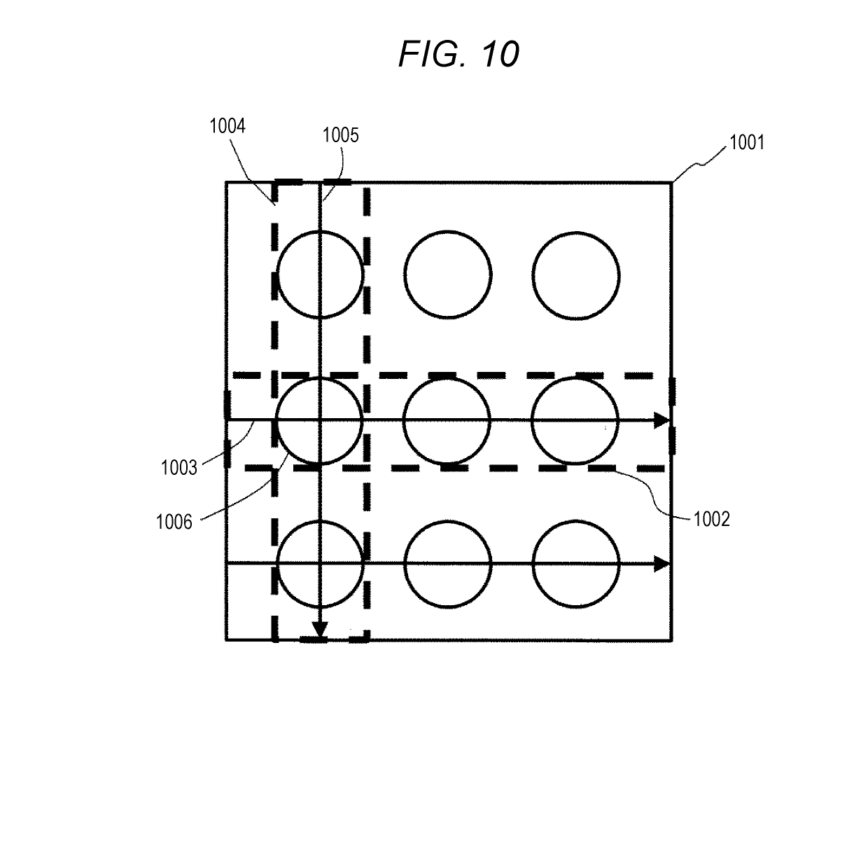

FIG. 10 is a drawing illustrating an X-direction (first direction) reference waveform obtaining area 1002 and a Y-direction (second direction) reference waveform obtaining area 1004 that are set in a field of view (scanning area) 1001. As described above, even if a part having no pattern is scanned, a waveform that includes a referential peak cannot be obtained. Therefore, a reference waveform obtaining line or a reference waveform obtaining area (reference waveform obtainable area) is set so as to include an edge of a hole pattern 1006, and an X-direction scanning line 1003 and a Y-direction scanning line 1005 are scanned therein. In addition, if a scanning area is a surface, the charged amount becomes large as described above, which produces a deflection effect. Therefore, a reference waveform is generated in such a manner that scanning can be considered to be a line (scanning from one scanning line to several scanning lines). For example, in a case where an integrated image composed of eight frames is generated, on the assumption that the number of scanning lines (the cumulative number) for a reference waveform is also eight, the cumulative number of the reference waveform and that of the image signal described later agree with each other, and therefore a comparison and determination can be made with high accuracy.

Next, two-dimensional scanning is performed by an arbitrary scanning method to obtain an image. A signal waveform (second signal waveform) at the same position as that of the first signal waveform is extracted from the obtained image. The control device controls a scanning deflector in such a manner that a beam is scanned over a surface area that includes a scanning region of one-dimensional scanning, and that is wider than the scanning region.

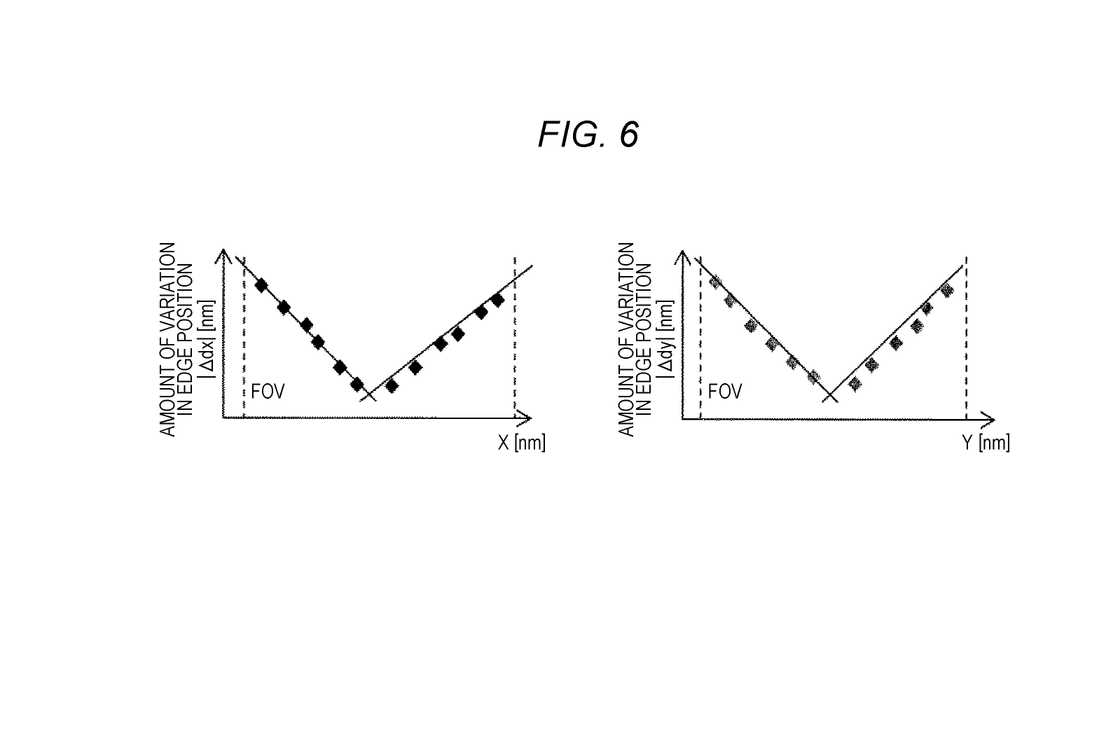

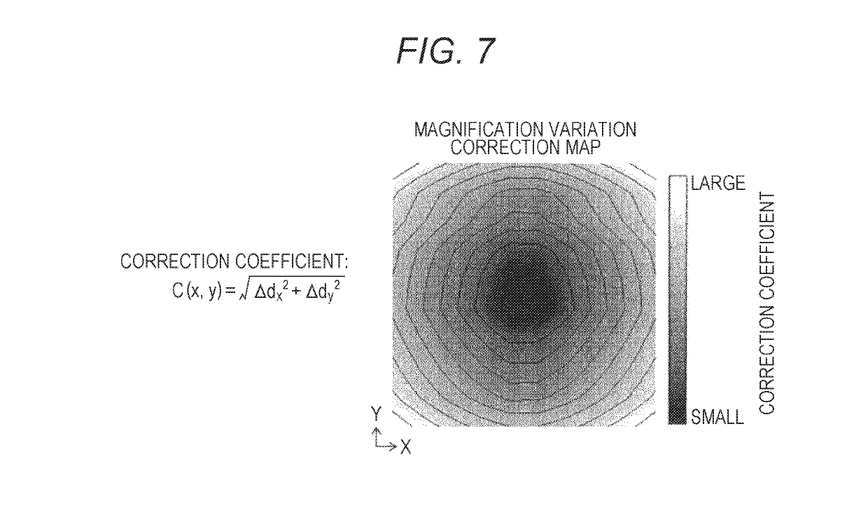

Next, two waveforms are compared, and from a comparison between waveform characteristic positions such as peaks of pattern edges, the amount of deviation in arrival position of primary electrons as indicated in FIG. 6 is determined with respect to X, Y coordinates in the field of view. Here, the amount of deviation in X direction and the amount of deviation in Y direction are each one dimensional, and therefore the amount of in-plane two-dimensional deviation is determined by using [Mathematical Formula 1] (FIG. 7). Here, Δdx represents the amount of deviation in arrival of primary electrons at a position x, and Δdy represents the amount of deviation in arrival of primary electrons at a position y. As described above, correction data such as a two-dimensional dimension correction table (or correction equation) is determined, and a dimension value of each coordinate is corrected.

C(x,y)=\sqrt{Δdₓ²+Δd_{y}²}[ Mathematical Formula 1]

The obtained image or the dimension value may be subjected to correction. Alternatively, a correction may be reflected in a lookup table. In a case where an object to be measured and observation conditions (scanning method, observation magnification, irradiation voltage, irradiation current) are identical, dimensional variations are considered to be identical. Accordingly, the same correction table (or correction equation) may be applied.

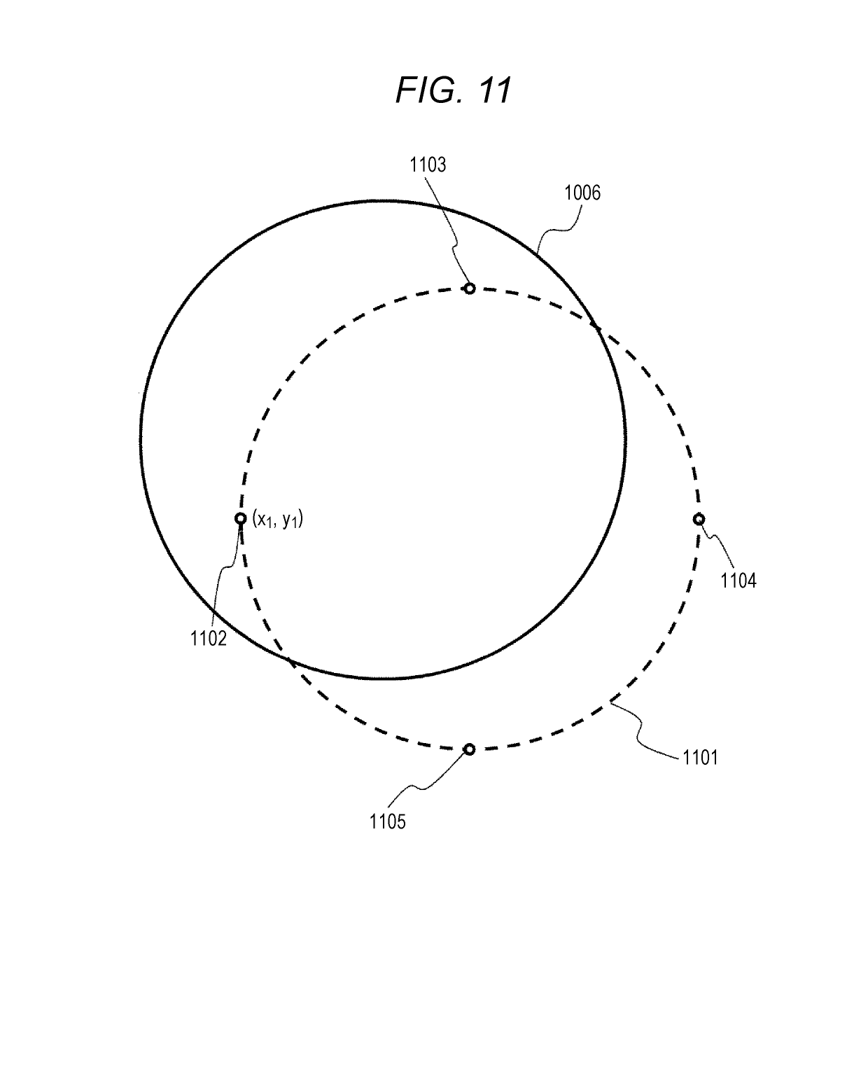

FIG. 11 is a drawing illustrating the positional relationship on an image between the hole pattern 1006 obtained by two-dimensional scanning, in which the number of scanning lines (for example, 512) scanned is larger than that of one-dimensional scanning, and a pattern 1101 obtained by scanning a beam that is not influenced by a deflection effect produced by electrification.

First of all, on the basis of the detection of a peak of a signal waveform obtained by one-dimensional scanning of a beam on the X-direction scanning line 1003, X-coordinate information in a field of view of an edge point (left) 1102 and an edge point (right) 1104 is detected. As described above, electric charges do not adhere as a surface by one-dimensional scanning, and therefore there is a low possibility that the beam will be deflected by electrification. Accordingly, it is possible to determine that a primary beam arrival position and an actual beam arrival position agree with each other. Therefore, it is possible to define that Y-coordinates of the edge point (left) 1102 and the edge point (right) 1104 are the same as Y-coordinate of the X-direction scanning line in the field of view. As the result, coordinates of the edge points (in the case of the edge point (left) 1102, (x₁, y₁)) are identified. In the case of the edge point (top) 1103 and the edge point (bottom) 1105 as well, coordinates of the edge points are identified on the basis of the one-dimensional scanning as described above. With respect to the edge point (top) 1103 and the edge point (bottom) 1105, edge coordinates are identified on the basis of a signal obtained by beam scanning on the Y-direction scanning line 1005.

Next, an image of the hole pattern 1006 is generated by performing two-dimensional scanning in the field of view. In addition, matching processing is performed among the image of the hole pattern 1006, or a contour line obtained by thinning processing of an edge part of the hole pattern 1006, and four edge points, thereby performing alignment. The alignment processing is executed by, for example, image processing that moves at least any of the hole pattern and the edge points in such a manner that the edge or contour line of the hole pattern 1006 gets closest to the four edge points. More specifically, the alignment is executed in such a manner that an added value of a deviation of the hole pattern from each edge point is minimized. The amount of movement (Δxₘ, Δyₘ) at this point of time is stored in a predetermined storage medium.

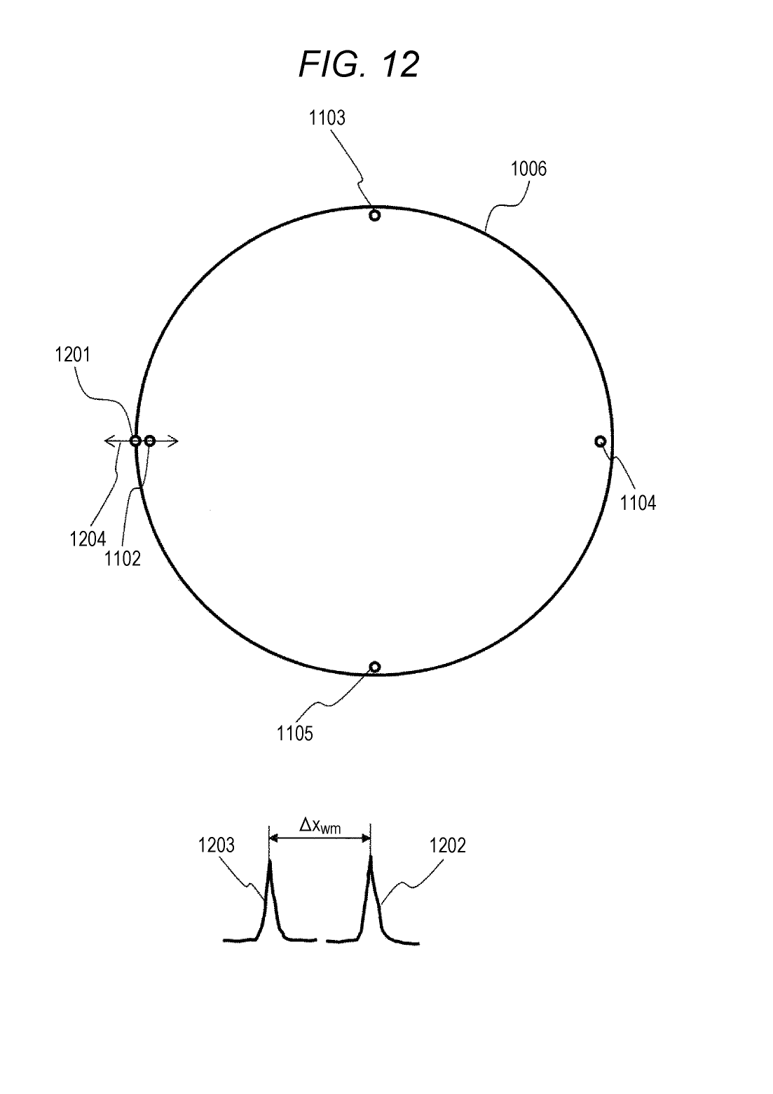

FIG. 12 is a drawing illustrating, as example, an image obtained after alignment processing is performed between a hole pattern image and edge points. An influence of electrification causes not only variation in pattern position, but also deformation, and consequently a position of an edge point obtained by one-dimensional scanning differs from a position of an edge of a circular pattern obtained by two-dimensional scanning. Accordingly, a deviation derived from the deformation is calculated by computing a difference between an edge point 1201 of the hole pattern on the same x-axis as that of the edge point (left) 1102, and the edge point (left) 1102. The difference between the edge point (left) 1102 and the edge point 1201 is calculated by, for example, waveform matching between a first signal waveform (peak waveform 1202) obtained by one-dimensional scanning, and a brightness signal waveform (peak waveform 1203) obtained at the edge point 1201 that is a corresponding point of the edge point (left) 1102 of the hole pattern 1006. The peak waveform 1203 is obtained on the same x-axis as that of the edge point (left) 1102.

An added value (Δxₘ+Δx_{wm}, Δyₘ) of a difference Δx_{wm} obtained by the waveform matching and the amount of movement (Δxₘ, Δyₘ) obtained by the matching processing becomes the amount of deviation from the primary position of the edge point 1201. Therefore, (−(Δxₘ+Δx_{wm}), −Δyₘ) is registered as a correction value of coordinates (x₁+Δxₘ+Δx_{wm}, y₁+Δyₘ) in the field of view.

The processing as described above is also performed for the other edge points, and thereby correction amounts of a plurality of positions are calculated. In addition, the processing is also performed for the other patterns, and thereby the correction amount at each position in the field of view is calculated. Moreover, the correction amounts of the other positions in the field of view may be determined by interpolation by using an interpolation method from the calculated correction amount. Further, an arithmetic expression or a table, which uses coordinates as a parameter, is created beforehand, and a coordinate position in a two-dimensional image may be corrected by inputting coordinates information of the two-dimensional image.

It should be noted that the above-described calculation method for calculating a correction value is merely an example. Therefore, a proper calculation method may be employed according to a state of a deviation in pattern position, and a state of deformation.

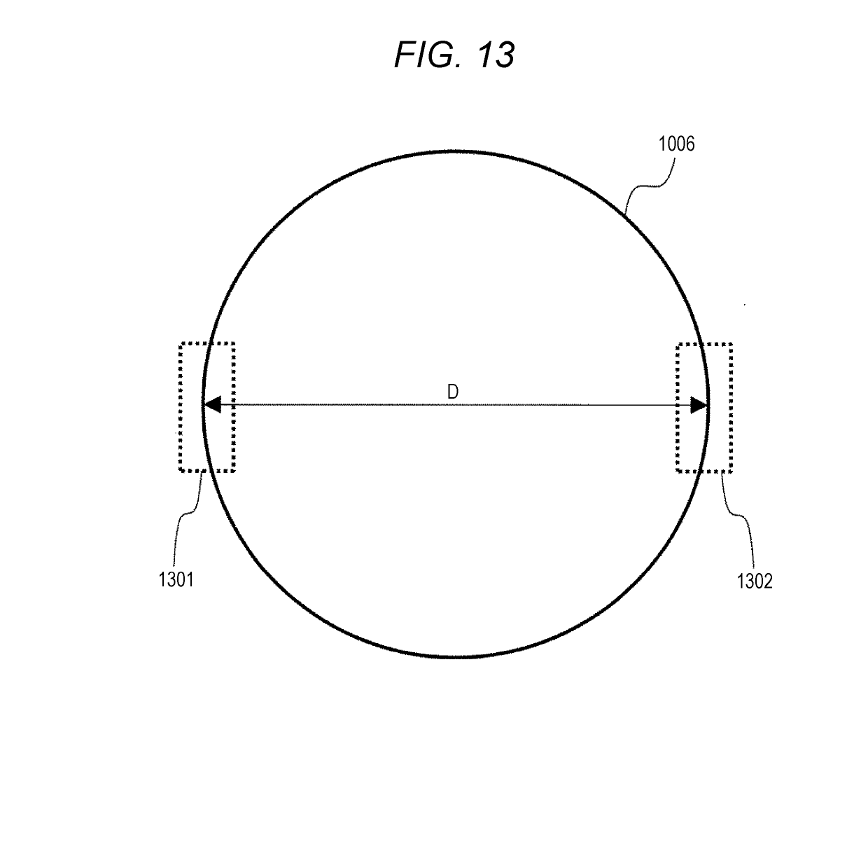

Moreover, in a case where pattern dimensions are measured, as presented in FIG. 13, such a program that automatically sets measurement areas 1301, 1302 in a two-dimensional image of the hole pattern 1006 is stored in a predetermined storage medium beforehand, and after the image is obtained by the arithmetic processing device, a dimension value D is computed by obtaining a brightness profile in the measurement areas 1301, 1302. Subsequently, on the basis of correction information set in the measurement areas 1301, 1302, the dimension value D is corrected to determine a dimension value D′. For example, in a case where the correction amount of the measurement area 1301 is Δdx1, and the correction amount of the measurement area 1302 is Δdx2, a true dimension value that is not influenced by electrification is calculated by D′=D−Δd1−Δdx2.

As described above, correcting the amount of variation in beam arrival position derived from electrification at each position in the two-dimensional image, and then outputting a measurement result or the like, enables to cope with both the generation of a two-dimensional image having no deviation in brightness in a field of view and high-accuracy pattern measurement.

Combination with Design Data

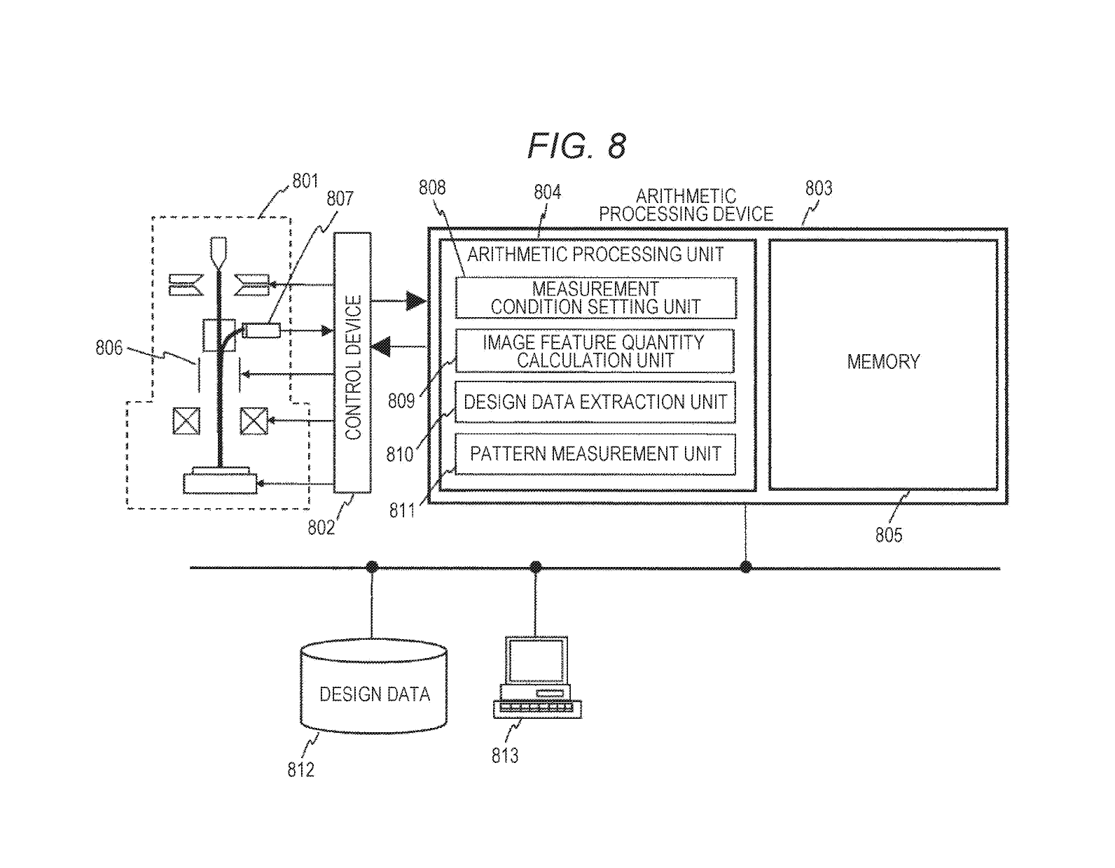

A control device of a scanning electron microscope is provided with not only a function of controlling each configuration of the scanning electron microscope, but also a function of forming an image on the basis of detected electrons, and a function of deriving feature points, such as a taper and a round, on the basis of the intensity distribution of detected electrons. FIG. 8 shows an example of a pattern measurement system provided with an arithmetic processing device 803.

This system includes a scanning electron microscope system that includes a SEM main body 801, a control device 802 of the SEM main body, and the arithmetic processing device 803. An arithmetic processing unit 804 that supplies a predetermined control signal to the control device 802, and that executes signal processing of a signal obtained by the SEM main body 801, and a memory 805 that stores obtained image information and recipe information, are built into the arithmetic processing device 803. It should be noted that in the present embodiment, although the control device 802 and the arithmetic processing device 803 are described as separate bodies, the control device 802 may be configured as a control device integrated therewith.

An electron emitted from a sample as the result of beam scanning by a deflector 806, or an electron generated by a conversion electrode, is picked up by a detector 807, and is then converted into a digital signal by an A/D converter built into the control device 802. The image processing according to the purpose is performed by image processing hardware, such as a CPU, an ASIC and a FPGA, which are built into the arithmetic processing device 803.

A measurement condition setting unit 808 that sets measurement conditions including scanning conditions of the deflector 806 on the basis of measurement conditions input by an input device 813, and an image feature quantity calculation unit 809 that determines, from obtained image data, a profile in a Region Of Interest (ROI) input by the input device 813, are built into the arithmetic processing unit 804. In addition, a design data extraction unit 810 that reads design data from a design data storage medium 812 according to a condition inputted by the input device 813, and that converts vector data into layout data as necessary, is built into the arithmetic processing unit 804. Further, a pattern measurement unit 811 that measures taper and round dimensions of a pattern on the basis of an obtained signal waveform is built into the arithmetic processing unit 804. The pattern measurement unit 811 makes a comparison between the first and second waveforms determined by the image feature quantity calculation unit 809 to determine the amount of positional deviation with respect to coordinates in the field of view. Moreover, a GUI for displaying an image, a result of inspection and the like for an operator is displayed on a display device provided in the input device 813 that is connected to the arithmetic processing device 803 through a network. For example, data can also be displayed as a correction map together with image data and design data.

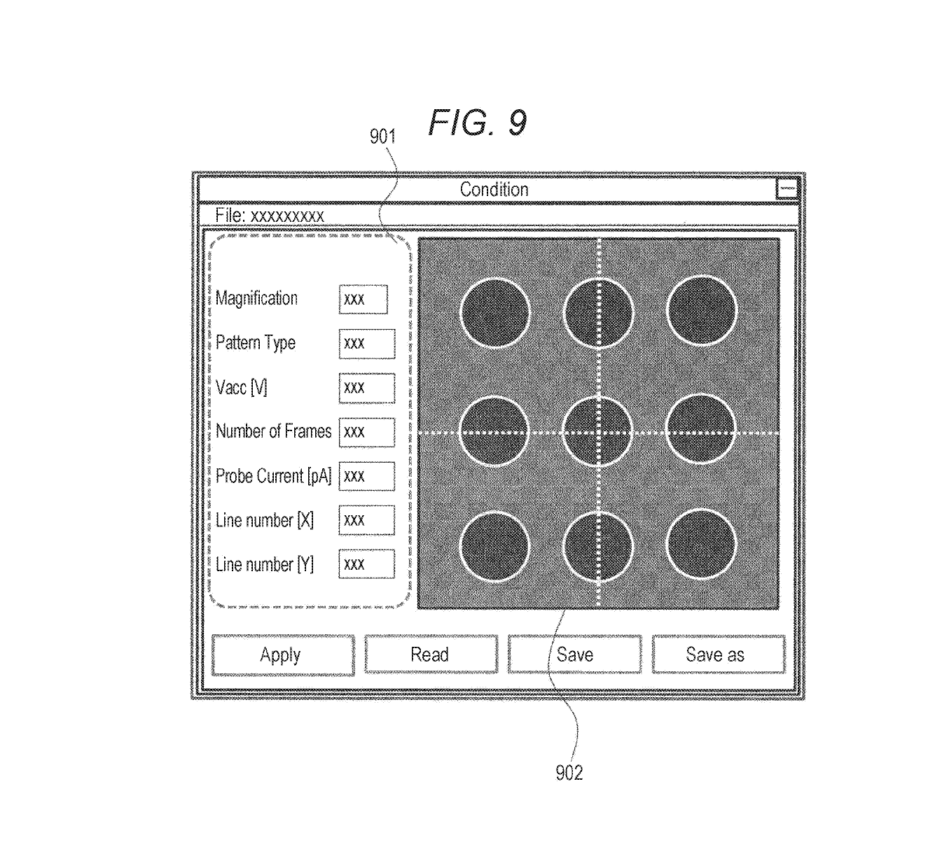

FIG. 9 is a drawing illustrating, as an example, a GUI screen used to set operating conditions of an SEM. For pattern information included in the field of view, an operator is allowed to arbitrarily specify a point at which a first signal waveform is obtained. The signal waveform obtaining point is specified on an image (or layout data) obtained beforehand. Settings are made by specifying an arbitrary two-dimensional area on an image 902 by a mouse or the like. The created correction table (map, correction equation) can be saved by being provided with a name, and can also be used by being called when an identical pattern at a different point is measured.

What is claimed is:

1. A charged particle beam device comprising: a scanning deflector that scans a charged particle beam emitted from a charged particle source; a detector that detects a charged particle obtained on the basis of scanning of the charged particle beam applied to a sample; a computing device that generates a signal waveform on the basis of an output of the detector, and computes pattern dimensions of a pattern formed on the sample by using the signal waveform; and a control device that controls the scanning deflector,
wherein when the control device controls the scanning deflector to perform scanning, the number of scanning lines of which being one or more, for a first region intersecting an edge of the pattern on the sample, the computing device generates a first signal waveform on the basis of the charged particle detected by the detector,
when the control device controls the scanning deflector to perform scanning, the number of scanning lines of which being larger than that at the time of scanning the first region, for a first area that includes the first region, and that is wider than the first region, the computing device generates a second signal waveform on the basis of the charged particle detected by the detector, and
the control device determines a deviation between the generated first and second signal waveforms.

2. The charged particle beam device according to claim 1, wherein
when the control device controls the scanning deflector to scan the charged particle beam in a first direction, the computing device generates the first signal waveform on the basis of the charged particle detected by the detector, and
when the control device controls the scanning deflector to scan the charged particle beam in a second direction that differs from the first direction, the computing device generates a different first signal waveform on the basis of the charged particle detected by the detector.

3. The charged particle beam device according to claim 1, wherein
the computing device generates the first signal waveform for a plurality of different positions in the first area.

4. The charged particle beam device according to claim 3, wherein
the computing device determines a deviation between the first signal waveform and the second signal waveform at the plurality of positions.

5. The charged particle beam device according to claim 4, wherein
the computing device generates correction data used to correct a deviation in an irradiation position of the charged particle beam on the basis of the plurality of deviations.

6. The charged particle beam device according to claim 5, wherein
when the control device controls the scanning deflector to scan the charged particle beam in the first area, the computing device measures dimensions of a pattern included in the first area on the basis of the charged particle detected by the detector, and corrects a result of the measurement by using a correction table or a correction equation.

7. The charged particle beam device according to claim 5, wherein
the control device controls the scanning deflector to cause the charged particle beam to be irradiated at a beam irradiation position corrected by the correction table or the correction equation.

8. The charged particle beam device according to claim 1, further comprising a display device that displays an image of the first area on the basis of the detection of a charged particle obtained by beam scanning for the first area,
wherein the computing device displays the image of the first area, and a dimension value of the pattern in the first area, the dimension value having been corrected according to the deviation between the first signal waveform and the second signal waveform.

9. A storage medium for storing a computer program that causes a computer to measure dimensions of a pattern to be measured on the basis of a measurement signal waveform obtained by a charged particle beam device, and that can be read by the computer,
the program causing the computer to: obtain a plurality of first signal waveforms obtained by performing scanning, the number of scanning lines of which is one or more, at a plurality of positions on a sample on which the pattern is formed, and image data obtained by beam scanning for an area that includes the plurality of positions; determine deviations of respective obtaining positions of the first signal waveforms at the plurality of positions from respective positions corresponding to obtaining positions of the first signal waveforms on the image data by comparing the first signal waveforms with second signal waveform data extracted from the image data; and generate, from the deviations at the plurality of positions, measurement-value correction data that uses the measurement signal waveforms.
